(19) United States
(12) Patent Application Publication
(10) Pub. No.: US 2013/0126731 A1
(43) Pub. Date: May 23, 2013

(54) Charged Particle Microscope and Ion Microscope

(71) Applicants: Hiroyasu Shichi, Tokyo (JP); Shinichi Matsubara, Chofu (JP); Yoichi Ose, Mito (JP); Yoshimi Kawanami, Hitachinaka (JP)

(72) Inventors: Hiroyasu Shichi, Tokyo (JP); Shinichi Matsubara, Chofu (JP); Yoichi Ose, Mito (JP); Yoshimi Kawanami, Hitachinaka (JP)

(73) Assignee: Hitachi High-Technologies Corporation, Minato-ku, Tokyo (JP)

(21) Appl. No.: 13/521,588

(22) PCT Filed: Feb. 4, 2011
(86) PCT No.: PCT/JP2011/000629

§ 371 Date: Jan. 24, 2013

(30) Foreign Application Priority Data
Feb. 8, 2010 (JP) 2010-024997

(51) Int. Cl. H01J 37/26

(52) U.S. Cl. CPC H01J 37/261
USPC 250/310; 250/428; 250/429

(57) ABSTRACT

In order to provide a safe and environmentally-friendly charged gas particle microscope that exhibits a superior ionized gas-utilization efficiency and economic efficiency, the gas field ion source of a charged particle microscope is equipped with a vacuum chamber in which are provided a vacuum chamber evacuation mechanism, an acicular emitter tip, an extraction electrode disposed facing the emitter tip, and a mechanism for supplying a gas to the vicinity of the emitter tip, and is configured so that the gas in the region around the tip of acicular ion emitter is ionized and extracted as an ion beam. Therein, the evacuation mechanism and the gas supply mechanism are connected, and a material for adhering the gas to be ionized is disposed between the evacuation mechanism and the gas supply mechanism.

### TECHNICAL FIELD

The present invention relates to a charged particle microscope and ion microscope.

### BACKGROUND ART

Electrons are irradiated to a sample while being swept in order to scan the sample, and secondary charged particles released from the sample are detected, whereby the structure of a sample surface can be observed. This is called a scanning electron microscope (hereinafter, abbreviated town SEM). In contrast, even when an ion beam is irradiated to the sample while being swept in order to scan the sample, and the secondary charged particles released from the sample are detected, the structure of the sample surface can be observed. This is called a scanning ion microscope (hereinafter, abbreviated to an SIM). In particular, when an ionic species of a small mass such as hydrogen or helium is irradiated to the sample, a sputtering effect gets relatively diminished. This is preferable for observation of the sample.

Further, compared with an electron beam, an ion beam is characteristic of being sensitive to information on a sample surface. This is because compared with irradiation of the electron beam, a region excited by secondary charged particles is more markedly localized on the sample surface. In addition, as for the electron beam, since the nature as a wave of electrons cannot be ignored, an aberration occurs due to a diffractive effect. In contrast, as for the ion beam, since ions are heavier than electrons, the diffractive effect can be ignored.

An electron beam is irradiated to a sample, and electrons transmitted by the sample are detected, whereby information reflecting the structure of a sample interior can be obtained. Likewise, even when an ion beam is irradiated to the sample, and ions transmitted by the sample are detected, the information reflecting the structure of the sample interior can be obtained. This is called a transmission ion microscope. In particular, when an ion species having a small mass such as hydrogen or helium is irradiated to the sample, a ratio of ions, which are transmitted by the sample, gets larger. This is preferable for observation.

In contrast, when an ion species having a large mass such as oxygen, nitrogen, argon, krypton, xenon, gallium, or indium is irradiated to a sample, the sample is preferably processed owing to a sputtering effect. In particular, a focused ion beam (FIB) apparatus employing a liquid metal ion source (hereinafter, LMIS) is known as an ion beam processing apparatus. In addition, gas ions of oxygen, nitrogen, argon krypton, or xenon may be produced using a plasma ion source or gas field ion source, and irradiated to the sample. Thus, the sample may be processed.

By the way, for an ion microscope intended mainly for sample observation, a gas field ion source is preferred as an ion source. The gas field ion source is such that a gas such as hydrogen or helium is supplied to a metallic emitter tip whose distal end has a radius of curvature of about 100 nm, a high voltage of several kilovolts or more is applied to the emitter tip, and gas molecules are thus field-ionized and extracted as an ion beam. The ion source is characterized by the capability of producing an ion beam that has a narrow energy width. In addition, the size of an ion generation source is so small that a microscopic ion beam can be produced.

In an ion microscope, for observing a sample at a high signal-to-noise ratio, it is necessary to obtain an ion beam of a large electric current density on the sample. It is therefore necessary to increase the electric current density at an ion radiation angle of a field ionization ion source. In order to increase the ion-radiation angle electric current density, a molecular density of an ion material gas (ionization gas) in the vicinity of an emitter tip should be increased. A gas molecular density per a unit pressure is inversely proportional to the temperature of a gas. Therefore, the emitter tip should be cooled down to extremely low temperature in order to lower the temperature of the gas around the emitter tip. Accordingly, the molecular density of the ionization gas in the vicinity of the emitter tip can be increased. The pressure of the ionization gas around the emitter tip can be brought to the range from about 10⁻² Pa to about 10 Pa.

However, when the pressure of an ion material gas is 1 Pa or more at most, an ion beam collides with a neutral gas and is neutralized. Therefore, an ion current diminishes. In addition, if the number of gas molecules in a field ionization ion source increases, a frequency at which the gas molecules that collide against the wall of a high-temperature vacuum chamber and take on high temperature collide against an emitter tip rises. Therefore, the temperature of the emitter tip rises, and the ion current diminishes. For this reason, the field ionization ion source is provided with a gas ionization chamber that mechanically encloses the perimeter of the emitter tip. The gas ionization chamber is formed by utilizing an ion extraction electrode opposed to the emitter tip.

Patent literature 1 has disclosed that an ion source characteristic is improved by forming a microscopic jut at the distal end of an emitter tip. Non-patent literature 1 has disclosed that a microscopic jut at the distal end of an emitter tip is formed using a second metal different from an emitter tip material. Non-patent literature 2 has disclosed a scanning ion microscope including a gas field ion source that emits helium ions.

Patent literature 2 has disclosed a scanning charged-particle microscope including a gas field ion source that includes an extraction electrode which forms an electric field, which ionizes a gas, in the vicinity of the distal end of an emitter and a cooling means that cools the emitter, a lens system that focuses ions extracted from the gas field ion source, a beam deflector that sweeps an ion beam, a secondary particle detector that detects secondary particles, and an image display means that displays a scanning ion microscope image. Also disclosed is that: a beam is swept on a movable beam limiting aperture owing to a deflection effect of an upper beam deflector aligner; and a scanning ion microscope image is constructed using a signal synchronous with a scanning signal as an XY signal and a secondary-electron detection intensity as a Z (luminance) signal, and is displayed on a monitor of the image display means. Further disclosed is that the scanning ion microscope image on the monitor screen has an equivalent image thereof obtained by convoluting and blurring a field ion microscope image at an ion radiation solid angle equivalent to an aperture stop of the movable beam limiting aperture.

Patent literature 3 has disclosed a technique that a surface cleaning means is disposed at an electron gun or gallium liquid metal ion source, and used to remove an amorphous contamination membrane that has adhered to, for example, a carbon nanotube surface or gallium surface. As the surface cleaning means, a reactive gas introduction means or activation means has been disclosed. In addition, when a reactive gas is hydrogen, a case where a hydrogen storing alloy is employed has been disclosed. However, a method of supplying gallium that is a material of an ion beam has not been disclosed at all.

Patent literature 4 has disclosed that in a charged particle radiation apparatus, a non-evaporable getter is allowed to adsorb hydrogen in a gas field ion source, and hydrogen released by heating the non-evaporable getter is used as an ionization gas.

Patent literature 5 has disclosed a structure in which a solution containing an ionic liquid is released to a gas phase according to an electrospray technique, and necessary ions alone is transported to the interior of an ion source, and has disclosed that the ionic liquid which has not been used as an ion beam is collected and reused.

### CITATION LIST

### Patent Literatures

Patent literature 1: JAPANESE UNEXAMINED PATENT APPLICATION PUBLICATION NO. 58-85242
Patent literature 2: Japanese Unexamined Patent Application Publication No. 2008-140557
Patent literature 3: Japanese Patent Application No. 2005-364657
Patent literature 4: Japanese Unexamined Patent Application Publication No. 2009-163981
Patent literature 5: Japanese Unexamined Patent Application Publication No. 2009-87594

### Non-Patent Literatures

Non-patent document 1: “Nano Letters” by H. S. Kuo, I. S. Hwang, T. Y. Fu, J. Y. Wu, C. C. Chang, and T. T. Tsong (4, 2004, 2379)
Non-patent document 2: “Microscopy Today” by J. Morgan, J. Notte, R. Hill, and B. Ward (Jul. 14, 2006, 24)

### SUMMARY OF THE INVENTION

### Technical Problems

A gas field ion source having a nano-pyramid structure at the distal end of a metallic emitter is confronted with a problem described below. Namely, the ion source is characterized by employment of ions released from near one atom at the distal end of the nano-pyramid. Specifically, a region from which ions are released is narrow, and an ion light source is so small as to have a nanometer or less in size. Therefore, a current per a unit area or unit solid angle, that is, a luminance is high.

When the ion light source is focused on a sample at an unchanged magnification or focused on the sample with a reduction ratio set to a fraction or so, a beam diameter ranging from, for example, about 0.1 nm to about 1 nm is attained. In other words, observation at a super resolution ranging from about 0.1 nm to about 1 nm is realized.

By the way, in an ion microscope, for observing a sample at a high signal-to-noise ratio, it is necessary to obtain an ion beam of a large electric current density on the sample. For this purpose, it is necessary to increase an electric current density at an ion radiation angle of a gas field ion source. In order to increase the ion-radiation angle electric current density, a molecular density of an ion material gas (ionization gas) in the vicinity of an emitter tip should be increased. A gas molecular density per a unit pressure is inversely proportional to the temperature of a gas. Therefore, the emitter tip is cooled down to extremely low temperature in order to lower the temperature of the gas around the emitter tip. Accordingly, the molecular density of the ionization gas in the vicinity of the emitter tip can be increased. Likewise, in order to increase the molecular density of the ion material gas (ionization gas), a gas ionization chamber that mechanically encloses the perimeter of the emitter tip is included. Thus, the pressure of the ionization gas around the emitter tip is raised to, for example, the range from about 10⁻² Pa to about 10 Pa.

However, an entire emission current of a gas field ion source is as small as several hundreds of picoamperes. Namely, even when an ionization gas is supplied to the perimeter of an emitter tip, only a small quantity of the gas is transformed to ions and the remaining quantity of the gas is almost exhausted by a vacuum pump. Therefore, a ratio at which an ion material gas is used as an ion beam is very low. This poses a problem in that raw material utilization efficiency is poor. The present inventor has noted that this leads not only to poor economic efficiency but also to wasting of a resource or degradation of energy utilization efficiency, and contradicts global environment protection.

In addition, in case an ionization gas is a reactive gas such as hydrogen, a gas larger than a necessary quantity may be placed near an apparatus by means of a high-pressure gas cylinder, high-concentration gas may be preserved in a pipe, or the gas is exhausted to the air. Therefore, it is necessary to take safety measurements. This leads to an increase in an apparatus cost. The present inventor has found that this problem becomes obvious in a gas field ion source, an entire emission current of which, compared with that of an existing ion source which utilizes gas plasma in which an ion current ranging from several microamperes to several amperes is produced, is as small as several hundreds of picoamperes.

An object of the present invention is to provide a charged particle microscope and ion microscope which exhibit high ionization gas utilization efficiency and excellent economic efficiency.

### Solution to the Problems

The present invention provides a charged particle microscope including a vacuum chamber, a first pump that exhausts the vacuum chamber, an emitter tip disposed in the vacuum chamber, an extraction electrode opposed to the emitter tip, and a gas supply means that supplies a gas to the emitter tip. Herein, the gas supply means includes a second pump that circulates a gas which is not used at the emitter tip. The second pump includes a gas adsorption material that adsorbs the gas.

Further, the charged particle microscope includes a temperature control means that controls the temperature of the gas adsorption material.

Further, the charged particle microscope includes a means for heating the gas adsorption material and a temperature control means for cooling the gas adsorption material.

Further, a gas id adsorbed by the gas adsorption material in advance, and the first pump is driven.

Further, the gas adsorption material is a non-evaporable getter.

Further, the gas supply means includes a first channel that is a gas channel extending from the vacuum chamber to a first vacuum chamber in which the gas adsorption material is accommodated, a second channel that is a gas channel extending from the first vacuum chamber to the vacuum chamber, and a gas selective-permeation means that selectively permeates a gas into the second channel.

Further, a valve is disposed in the first channel.

Further, a valve is formed in the first channel and second channel.

Further, the first vacuum chamber is provided with a third pump.

Further, the gas selective-permeation means is a hydrogen selective-permeation membrane.

Further, the gas is hydrogen.

Further, the gas contains at least one of hydrogen, helium, neon, argon, krypton, and xenon.

Further, the emitter tip is realized with a nano-pyramid.

An ion microscope includes a vacuum chamber, a first pump that exhausts the vacuum chamber, an emitter tip disposed in the vacuum chamber, an extraction electrode opposed to the emitter tip, a gas supply means that supplies a gas to the emitter tip, a focusing lens that focuses an ion beam emitted from the emitter tip, a deflector that deflects the ion beam transmitted by the focusing lens, a secondary particle detector that irradiates the ion beam to a sample and detects secondary particles released from the sample. Herein, the gas supply means includes a second pump that circulates a gas that is not used at the emitter tip, and, the second pump includes a gas adsorption material which adsorbs the gas.

A charged particle microscope includes a vacuum chamber, a first pump that exhausts the vacuum chamber, an emitter tip disposed in the vacuum chamber, an extraction electrode opposed to the emitter tip, a gas supply means that supplies a gas to the emitter tip, a focusing lens that focuses a charged particle beam emitted from the emitter tip, a deflector that deflects the charged particle beam which has passed through the focusing lens, and a secondary particle detector that irradiates the charged particle beam to a sample and detects secondary particles released from the sample. Herein, a positive voltage or negative voltage can be selectively applied to the emitter tip. The gas supply means includes a second pump that circulates a gas that is not used at the emitter tip, and the second pump includes a gas adsorption material which adsorbs the gas.

Further, the gas includes one of hydrogen and helium and at least one of neon, argon, krypton, xenon, nitrogen, and oxygen.

Further included is a selection means capable of selecting a mode in which an ion beam deriving from at least one of gases of neon, argon, krypton, xenon, nitrogen, and oxygen is utilized through the emitter tip in order to process a sample, a mode in which an ion beam deriving from one of gases of hydrogen and helium is utilized through the emitter tip in order to observe a sample, or a mode in which an electron beam stemming from the emitter tip is utilized in order to observe a sample.

Incidentally, when a voltage is applied between the emitter tip and extraction electrode and a gas is supplied to the emitter tip, the gas is ionized at the distal end of the emitter tip. This is used as an ion beam. Out of the gas supplied to the perimeter of the emitter tip, a gas that is not ionized shall be expressed, in this specification, as a gas that is not used at the emitter tip.

### Advantageous Effects of the Invention

According to the present invention, ionization gas utilization efficiency can be improved and economic efficiency can be upgraded.

### BRIEF DESCRIPTION OF DRAWINGS

FIG. 1 is a schematic constitution diagram of an example of a charged particle microscope in accordance with the present invention;

FIG. 2 is a diagram of an example of a gas field ion source of the charged particle microscope in accordance with the present invention;

FIG. 3 is a schematic constitution diagram of a control system of an example of the charged particle microscope in accordance with the present invention;

FIG. 4 is a diagram of an example of the gas field ion source of the charged particle microscope in accordance with the present invention; and

FIG. 5 is a diagram of an example of the charged particle microscope in accordance with the present invention.

### DESCRIPTION OF EMBODIMENTS

An embodiment of the present invention is a gas field ion source in which an evacuation mechanism for a vacuum chamber, an acicular emitter tip, an extraction electrode opposed to the emitter tip, a mechanism for supplying a gas to the perimeter of the emitter tip are disposed in the vacuum chamber. The gas is ionized in the distal region of the acicular ion emitter, and extracted as an ion beam. Herein, the evacuation mechanism and the mechanism for supplying the gas are connected to each other. Between the vacuum chamber and the mechanism for supplying the gas, material that adsorbs the gas which should be ionized is disposed.

According to the constitution, a gas that is an ion source material is supplied to the perimeter of the emitter tip, ionized in the distal region of the acicular ion emitter, and then extracted as an ion beam. Owing to the material that adsorbs the gas which should be ionized, gas that is not ionized is adsorbed and desorbed as gas. The gas is supplied to the perimeter of the emitter tip, ionized in the distal region of the acicular ion emitter, and extracted as an ion beam. This has the advantage that a gas field ion source exhibiting high ionization gas utilization efficiency, excellent economic efficiency, and even well consistency with global environment protection is provided.

Further, the foregoing gas field ion source may be provided with a temperature controller for the material that adsorbs a gas which should be ionized. This has the advantage that since an adsorbing quantity and desorbing quantity can be controlled, a gas field ion source capable of more efficiently utilizing an ionization gas is provided.

Further, the aforesaid gas field ion source may be provided with a heating unit and cooling unit for the material that adsorbs a gas which should be ionized. This has the advantage that a gas field ion source capable of more efficiently utilizing an ionization gas by enabling desorption of a larger quantity through heating and enabling adsorption of a larger quantity through cooling is provided.

Further, in the aforesaid gas field ion source, after a gas which should be ionized is stored in advance in the material that adsorbs the gas which should be ionized, the gas field ion source may be evacuated. This has the advantage that a long-service life gas field ion source capable of introducing a large quantity of a gas into a vacuum unit is provided.

Further, in the aforesaid gas field ion source, the material that adsorbs a gas which should be ionized may be realized with a non-evaporative getter material. This has the advantage that a gas field ion source that improves the degree of vacuum of the vacuum chamber, diminishes adsorption of an impurity gas by the acicular ion emitter, stabilizes an ion beam, and exhibits high ionization gas utilization efficiency is provided.

Further, in the aforesaid gas field ion source, a material that selectively transmits a gas which should be ionized may be interposed between the material that adsorbs the gas which should be ionized and the emitter tip. Thus, an impurity gas is removed from gas desorbed from the material that adsorbs the gas which should be ionized. This has the advantage that a gas field ion source capable of diminishing adsorption of the impurity gas by the acicular ion emitter, stabilizing an ion beam, and exhibiting high ionization gas utilization efficiency is provided. This is attributable to the fact that the present inventor has brought it, which has not been discussed in the past, to light that a phenomenon that an impurity gas is released at the same time when gas is desorbed from a material that adsorbs the gas which should be ionized adversely affects stability of an ion beam.

Further, in the aforesaid gas field ion source, a valve capable of performing vacuum blocking is interposed between the material that adsorbs a gas which should be ionized and the vacuum chamber. This has the advantage that a gas field ion source that prevents an impurity gas, which is released at the same time when gas is desorbed from the material that adsorbs the gas which should be ionized, from being introduced into the vacuum chamber, diminishes adsorption of the impurity gas by the acicular ion emitter, stabilizes an ion beam, and exhibits high ionization gas utilization efficiency is provided.

Further, in the aforesaid gas field ion source, at least two or more pairs of valves capable of performing vacuum blocking are each interposed between the material that adsorbs a gas which should be ionized and the vacuum chamber. This has the advantage that a gas field ion source that, when gas is desorbed from the first material that adsorbs the gas which should be ionized, can retain the degree of vacuum in the vacuum chamber by closing the valve, which can perform vacuum blocking while being interposed between the material and vacuum chamber, and opening the other valve capable of performing vacuum blocking, diminishes adsorption of an impurity gas by the acicular ion emitter, stabilizes an ion beam, and exhibits high ionization gas utilization efficiency is provided.

Further, in the aforesaid gas field ion source, a vacuum pump that evacuates a vacuum chamber, which is separated with the valve capable of performing vacuum blocking and accommodates the material that adsorbs a gas which should be ionized, is disposed. This has the advantage that an impurity gas which is released at the same time when gas is desorbed from the material that adsorbs the gas which should be ionized can be discharged, and the vacuum chamber can be retained in high vacuum.

Further, in the aforesaid gas field ion source, the vacuum pump that exhausts the vacuum chamber includes a super-high vacuum pump and roughing pump, and a material that selectively transmits a gas which should be ionized is interposed between an exhaust port of the super-high vacuum pump and an intake port of the roughing pump. Accordingly, after gas is desorbed from the material that adsorbs the gas which should be ionized and an impurity gas is removed, the gas is supplied to the perimeter of the emitter tip, and ionized in the distal region of the acicular ion emitter. The resultant ions are extracted as an ion beam. This has the advantage that a gas field ion source exhibiting high ionization gas utilization efficiency is provided.

Further, in the aforesaid gas field ion source, hydrogen is adopted as the gas which should be ionized. This has the advantage that since a gas field ion source which exhibits higher ionization gas utilization efficiency due to high adsorption efficiency and high storage efficiency is provided. In addition, there is exerted the advantage that when a hydrogen ion beam is irradiated to a sample, a sample damage is limited compared with that caused by helium or the like.

Further, in the aforesaid gas field ion source, the distal end of the emitter tip is a nano-pyramid formed with atoms. This has the advantage that since an ionization region is limited, a higher-luminance ion source is formed and higher-resolution sample observation is enabled. In addition, since an entire ion current gets smaller, if an ionization gas is utilized in a circulative manner, there is exerted the advantage that a gas field ion source exhibiting higher ionization gas utilization efficiency is provided.

Further, a gas field ion source has an acicular emitter tip that produces ions, an extraction electrode opposed to the emitter tip, and an ionization chamber, which is formed to enclose the emitter tip, included in a vacuum chamber, and extracts an ion beam from the acicular emitter tip. The gas field ion source includes a first vacuum pump in which a non-evaporable getter joined to the vacuum chamber is incorporated, a mechanism that heats the non-evaporable getter, a valve capable of performing vacuum blocking while being interposed between the vacuum chamber and first vacuum pump, a second vacuum pump that exhausts the vacuum-blocked vacuum pump, and a piping that joins the vacuum pump and ionization chamber. Further, the gas field ion source has a hydrogen selective-permeation membrane in the middle of the piping. This has the advantage that a gas field ion source exhibiting high ionization gas utilization efficiency, excellent economic efficiency, and even well consistency with global environment protection is provided.

Further, a charged particle microscope includes the foregoing gas field ion source, a focusing lens that focuses an ion beam emitted from the ion source, a deflector that deflects the ion beam having passed through the focusing lens, and a secondary particle detector that detects secondary particles released from a sample. This has the advantage that a charged particle microscope exhibiting high ionization gas utilization efficiency, excellent economic efficiency, and even well consistency with global environment protection is provided.

Further, a charged particle microscopy is characterized in that: in the aforesaid gas field ion source, a gas is supplied to the perimeter of the emitter tip, gas that is not ionized by the gas field ion source is adsorbed by the material that adsorbs the gas which should be ionized, and the adsorbed gas is re-emitted and supplied to the perimeter of the emitter tip; and an ion beam is extracted from the gas field ion source, and used to observe or analyze a sample. This has the advantage that a charged particle microscopy exhibiting high ionization gas utilization efficiency, excellent economic efficiency, and even well consistency with global environment protection is provided.

Further, a hybrid charged particle microscope includes a hybrid particle source that has an emitter tip whose distal end is a nano-pyramid formed with atoms and that has an ion beam or electrons extracted from the acicular emitter tip thereof, a charged particle irradiation optical system that introduces charged particles emitted from the hybrid particle source to a sample, a secondary particle detector that detects secondary particles released from the sample, a charged particle imaging optical system that images the charged particles transmitted by the sample, and a gas supply pipe that supplies a gas to the vicinity of the emitter tip. As the gas, at least two kinds of gas species including one of hydrogen and helium and one of neon, argon, krypton, xenon, nitrogen, and oxygen can be selected. Either of a positive high voltage power supply and negative high voltage power supply can be selected and connected to the acicular emitter tip. This has the advantage that a charged particle radiation apparatus capable of observing a sample top surface using a beam of either hydrogen or helium, processing a sample using an ion beam of one of neon, argon, krypton, xenon, nitrogen, and oxygen, and observing a sample interior through irradiation of an electron beam to the sample and detection of electrons transmitted by the sample is provided. In particular, when a nano-pyramid emitter tip is employed, an extremely small-diameter ion beam and extremely small-diameter electron beam are obtained. This has the advantage that a charged particle microscope capable of analyzing sample information on the order of a sub-nanometer is provided.

Further, according to a hybrid charged particle radiation microscopy, the distal end of an emitter tip is a nano-pyramid formed with atoms. An ion beam of one of neon, argon, krypton, xenon, nitrogen, and oxygen is extracted from the acicular emitter tip, and irradiated to a sample in order to process the sample. An ion beam of one of hydrogen and helium is extracted from the acicular emitter tip in order to observe a sample surface. Electrons are extracted from the acicular emitter, and irradiated to the sample. Electrons transmitted by the sample are imaged in order to obtain sample interior information. This has the advantage that complex sample analysis based on observation of a sample surface, sample processing, and observation of a sample interior is enabled. In particular, when a nano-pyramid emitter tip is employed, there is exerted a charged particle microscopy enabling sample information analysis based on an extremely small-diameter ion beam and extremely small-diameter electron beam.

### Embodiment 1

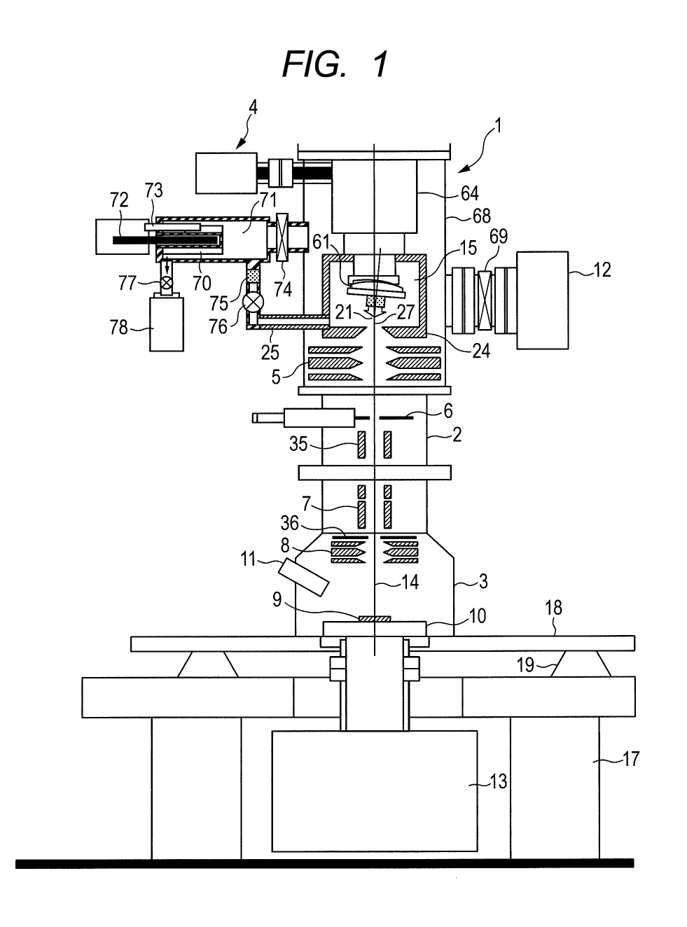

Referring to FIG. 1, an example of a charged particle microscope in accordance with the present invention will be described below. As an ion beam apparatus, a first example of a scanning ion microscope apparatus will be described. The scanning ion microscope of this example includes a gas field ion source 1, ion beam irradiation system column 2, sample chamber 3, and cooling mechanism 4. Herein, the interiors of the gas field ion source 1, ion beam irradiation system column 2, and sample chamber constitute a vacuum chamber.

The constitution of the gas field ion source 1 will be detailed later. In a vacuum chamber 68, an acicular emitter tip 21 and an extraction electrode 24 opposed to the emitter tip and having an opening 27 through which ions pass are incorporated. In addition, an ionization chamber 15 is formed in order to raise a gas pressure in the perimeter of the emitter tip.

Further, an ion source evacuation pump 12 that evacuates the vacuum chamber 68 of the gas field ion source 1 is included. A valve 69 capable of performing vacuum blocking is interposed between the vacuum chamber 68 and ion source evacuation pump 12. Further, a vacuum chamber 71 accommodating a non-evaporable getter 70 serving as a material that adsorbs a gas which should be ionized is connected to the vacuum chamber 68 of the gas field ion source 1. In addition, the non-evaporable getter is provided with a heating mechanism 72 and cooling mechanism 73 outside the vacuum chamber. The principle of the heating mechanism is resistive heating or lamp heating, and the cooling mechanism employs a coolant or a Peltier element. In addition, a valve 74 capable of performing vacuum blocking is interposed between the vacuum chamber 71 accommodating the non-evaporable getter 70 and vacuum chamber 68. The vacuum chamber accommodating the non-evaporable getter is connected to the ionization chamber 15 over a gas piping 25. Between the vacuum chamber 71 accommodating the non-evaporable getter 70 and ionization chamber 15, a material 75 that selectively permeates a gas which should be ionized is interposed for interruption, and a valve 76 capable of performing vacuum blocking is disposed. In addition, to the vacuum chamber accommodating the non-evaporable getter, a vacuum pump 79 is connected via a valve 77 capable of performing vacuum blocking.

Further, the gas field ion source 1 includes a tilting mechanism 61 that changes the inclination of the emitter tip 21 and employs a piezoelectric element. The tilting mechanism 61 is fixed to an emitter base mount 64. This is used to precisely align the direction of the distal end of the emitter tip with an ion beam irradiation axis 14A. Owing to the angle axis adjustment, there is exerted the advantage that the distortion of an ion beam is reduced.

An ion beam irradiation system includes a focusing lens 5 that focuses ions emitted from the gas field ion source 1, a first aperture 6 movable to limit an ion beam 14 having passed through the focusing lens, a first deflector 35 that sweeps or aligns an ion beam having passed through the first aperture, a second deflector 7 that deflects the ion beam having passed through the first aperture, a second aperture 36 that limits the ion beam having passed through the first aperture, and an objective lens 8 that focuses the ion beam, which has passed through the first aperture, on a sample.

Incidentally, a mass separator may be introduced into the ion beam irradiation system, though the mass separator is not shown. In addition, a structure capable of tilting the focusing lens with respect to the ion beam irradiation axis 14A may be included. When the tilting mechanism is formed with a piezoelectric element, the tilting mechanism can be realized relatively compactly.

Herein, what is referred to as the first deflector is, as described later, a deflector that sweeps an ion beam for the purpose of obtaining an ion radiation pattern from the emitter tip. The first deflector signifies a deflector that comes first from the ion source in the direction of a sample. However, a charged particle radiation apparatus may have a deflector, which is short compared with the length in an optical axis direction of the first deflector, disposed between the first deflector and focusing lens, and use the deflector to adjust a deflection axis of an ion beam.

In the sample chamber 3, a sample stage 10 on which a sample 9 is placed and the secondary particle detector 11 are disposed. An ion beam 14 from the gas field ion source 1 is irradiated to the sample 9 by way of the ion beam irradiation system. Secondary particles from the sample 9 are detected by the secondary particle detector 11. Herein, a signal quantity to be measured by the secondary particle detector 11 is nearly proportional to an ion beam current that has passed through the second aperture 36.

The ion microscope of the present example further includes a sample chamber evacuation pump 13 that evacuates the sample chamber 3. In addition, an electron gun for use in neutralizing a charging phenomenon of a sample occurring when an ion beam is irradiated to the sample, and a gas gun for use in etching or supplying a deposition gas to the vicinity of the sample are disposed.

On an apparatus gantry 17 installed on a floor 20, a base plate 18 is placed via a vibration isolation mechanism 19. The field ionization ion source 1, column 2, and sample chamber 3 are borne by the base plate 18.

The cooling mechanism 4 cools the interior of the field ionization ion source 1, emitter tip 21, and extraction electrode 24. In the present embodiment, a cooling channel is disposed inside the emitter base mount 64. Incidentally, for example, when a Gifford-McMahon refrigerator is used as the cooling mechanism 4, a compressor unit (compressor) using a helium gas as a working gas is installed on the floor 20, though the compressor unit (compressor) is not shown. Vibrations of the compressor unit (compressor) are propagated to the apparatus gantry 17 via the floor 20. A vibration removing mechanism 19 is interposed between the apparatus gantry 17 and base plate 18. High-frequency vibrations of the floor are characteristic of being hardly propagated to the field ionization ion source 1, ion beam irradiation system column 2, and vacuum sample chamber 3. Therefore, vibrations of the compressor unit (compressor) are characteristic of being hardly propagated to the field ionization ion source 1, ion beam irradiation system column 2, and sample chamber 3 by way of the floor 20. Herein, as a cause of the vibrations of the floor 20, the refrigerator 40 and compressor 16 have been described. However, the cause of the vibrations of the floor 20 is not limited to the refrigerator 40 and compressor 16.

The vibration isolation mechanism 19 may be formed with a vibration-proof rubber, spring, damper, or a combination thereof.

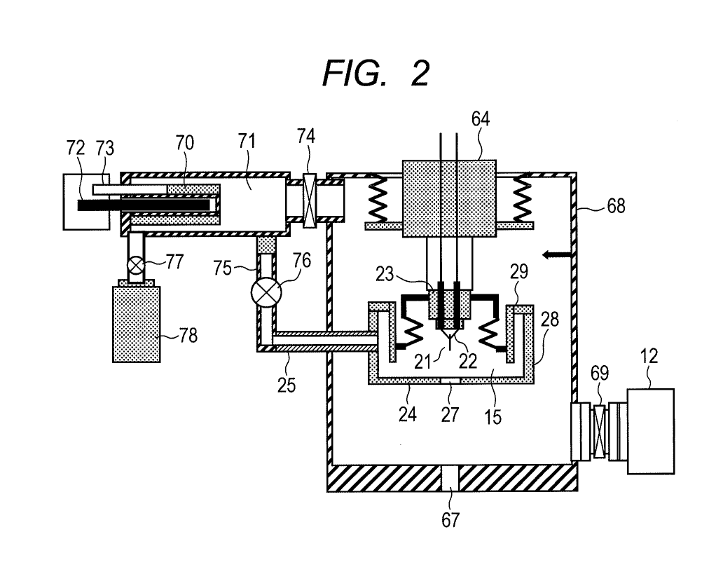

Referring to FIG. 2, components existent around an emitter tip of an example of the gas field ion source 1 of the charged particle microscope in accordance with the present invention will be described in detail. The gas field ion source of this example includes an emitter tip 21, a pair of filaments 22, a filament mount 23, and the emitter base mount 64. The emitter tip 21 is connected to the filaments 22. The filament mount 23 is fixed to the emitter base mount 64 with an insulator or the like between them. This makes it possible to apply a high voltage to the emitter tip 21. In addition, the ion source vacuum chamber 68 has an actuation vent 67 through which an ion beam passes.

The field ionization ion source of this example further includes the extraction electrode 24, a cylindrical sidewall 28, and a top panel 29. The extraction electrode 24 is opposed to the emitter tip 21, and has an opening 27 through which the ion beam 14 passes. Incidentally, a high voltage can be applied to the extraction electrode.

The sidewall 28 and top panel 29 enclose the emitter tip 21. A space surrounded by the extraction electrode 24, the sidewall 28, the top panel 29, an insulating material 63, and the filament mount 23 is called an ionization chamber 15 for gas molecules. Incidentally, the ionization chamber is a chamber for use in raising a gas pressure around the emitter tip, and is not limited to the elements forming the walls of the chamber.

The gas supply piping 25 is connected to the gas-molecule ionization chamber 15. Owing to the gas supply piping 25, a gas that should be ionized (ionization gas) is supplied to the emitter tip 21. In the present embodiment, the gas that should be ionized (ionization gas) is hydrogen.

The gas-molecule ionization chamber 15 is hermetically sealed except the hole 27 of the extraction electrode 24 and the gas supply piping 25. A gas supplied to the ionization chamber by way of the gas supply piping 25 does not leak out through any region other than the hole 27 of the extraction electrode and the gas supply piping 25. When the area of the opening 27 of the extraction electrode 24 is fully decreased, the gas-molecule ionization chamber can be held highly hermetic and sealable. When the opening of the extraction electrode is, for example, a round hole 27, the diameter is, for example, 0.3 mm. Therefore, when an ionization gas is supplied to the gas ionization chamber 15 through the gas supply piping 25, the gas pressure of the gas ionization chamber 15 becomes larger than the gas pressure of the vacuum chamber by at least one digit or more. Accordingly, a ratio at which an ion beam collides with gas in vacuum and gets neutralized decreases, and a large-current ion beam can be produced. The diameter of the actuation vent 67 is, for example, 2 mm. Therefore, the degree of vacuum of the vacuum chamber of the ion irradiation system through which an ion beam emitted from the ion source passes can be improved. Accordingly, the ratio at which the ion beam collides with the gas in the ion irradiation system vacuum chamber and gets neutralized is decreased. In other words, a current that reaches a sample is increased. In FIG. 2, the cooling mechanism for the emitter tip 21 is omitted.

Next, the structure of the emitter tip 21 and a production method will be described. To begin with, a tungsten wire whose diameter ranges from approximately 100 μm to approximately 400 μm and whose axial azimuth is <111> is procured, and the distal end thereof is sharply shaped. Accordingly, an emitter tip having a distal end whose radius of curvature is several tens of nanometers is obtained. Iridium is vacuum-evaporated to the distal end of the emitter tip using another vacuum chamber. Thereafter, platinum atoms are moved to the distal end of the emitter tip under high-temperature heating. Accordingly, a pyramid structure on the order of a nanometer is formed with iridium atoms. This shall be called a nano-pyramid. The nano-pyramid typically has one atom at the distal end thereof, has a layer of three or six atoms under the distal end, and has a layer of ten or more atoms under the layer.

In this example, a tungsten thin wire is employed. Alternatively, a molybdenum thin wire may be adopted. In this example, an iridium coating is employed. Alternatively, a coating of platinum, rhenium, osmium, palladium, or rhodium may be adopted.

As a method of forming a nano-pyramid at the distal end of the emitter tip, field evaporation in vacuum, gas etching, ion beam irradiation, or the like may be adopted. According to the method, a tungsten-atom or molybdenum-atom nano-pyramid can be formed at the distal end of a tungsten wire or molybdenum wire. For example, when a tungsten wire of <111> is employed, the distal end is formed with three tungsten atoms. Otherwise, a similar nano-pyramid may be formed at the distal end of a thin wire made of platinum, iridium, rhenium, osmium, palladium, or rhodium by utilizing an etching effect in vacuum. The emitter tip having a sharp distal structure on the order of atoms shall be called a nano-tip.

As mentioned above, the emitter tip 21 of the gas field ion source in the present embodiment is characterized by the nano-pyramid. By adjusting the intensity of an electric field formed at the distal end of the emitter tip 21, a helium ion can be produced in the vicinity of one atom at the distal end of the emitter tip. Therefore, a region from which an ion is emitted, that is, an ion light source is an extremely narrow region, and is a nanometer or less in size. By thus generating ions from the quite limited region, a beam diameter can be set to 1 nm or less. Therefore, a current value per a unit area or unit solid angle of an ion source gets larger. This is a very significant characteristic for obtaining a very small-diameter and large-current ion beam.

When a nano-pyramid having one atom at the distal end thereof is formed using platinum, rhenium, osmium, iridium, palladium, or rhodium, a current emitted from a unit area or unit solid angle, that is, an ion source luminance can be increased. This is preferred in order to decrease a beam diameter on a sample in an ion microscope or increase a current. However, when the emitter tip is fully cooled down and gas supply is sufficient, the distal end need not always be formed with one atom but may be formed with three, six, seven, or ten atoms. Nevertheless, satisfactory performance can be exerted. In particular, the present inventor has found that when the distal end is formed with the number of atoms that is equal to or larger than four and falls below ten, the ion source luminance can be raised, the distal atom is hardly evaporated, and a stable action can be performed.

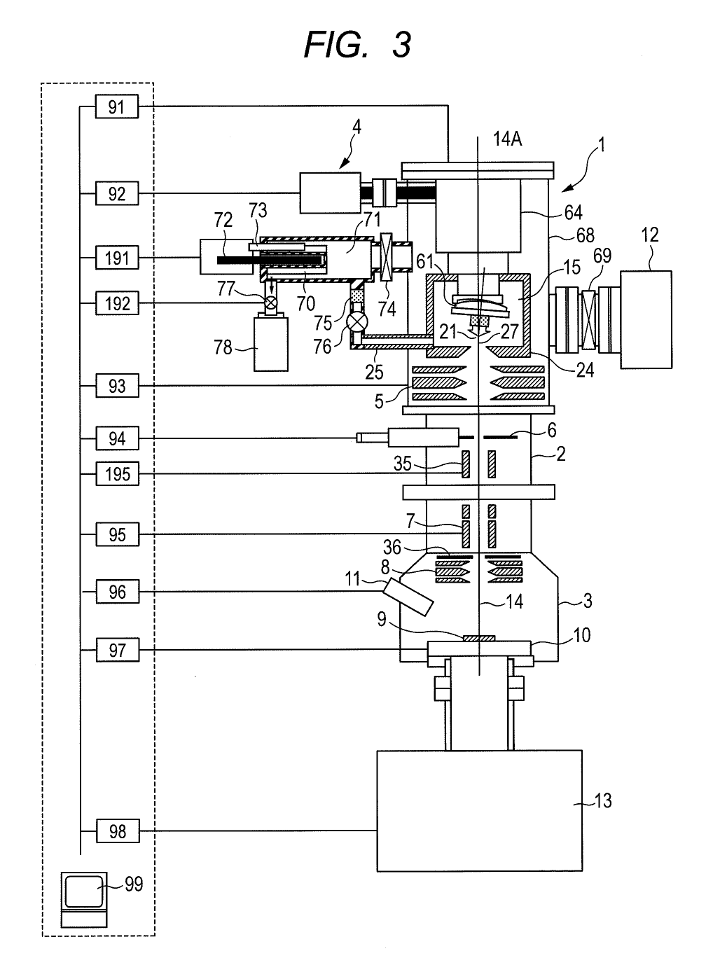

FIG. 3 shows an example of a control system for the ion microscope in accordance with the present invention shown in FIG. 1. The control system of this example includes a field ionization ion source controller 91 that controls the gas field ion source 1, a refrigerator, controller 92 that controls the refrigerator 40, a temperature controller 191 for the heating mechanism and cooling mechanism for the non-evaporable getter, a valve controller 192 that controls opening and closing of the plural valves 69, 74, 76, and 77 capable of performing vacuum blocking which being disposed around the gas field ion source, a lens controller 93 that controls the focusing lens 5 and objective lens, a first aperture controller 94 that controls the movable first aperture 6, a first deflector controller 195 that controls the first deflector, a second deflector controller 95 that controls the second deflector, a secondary particle detector controller 96 that controls the secondary particle detector 11, a sample stage controller 97 that controls the sample stage 10, an evacuation pump controller 98 that controls the sample chamber evacuation pump 13, and a calculation processing device 99 including an arithmetic unit. The calculation processing device 99 includes an image display unit. The image display unit displays an image produced from a detection signal of the secondary particle detector 11, and information inputted by an input means.

The sample stage 10 includes a mechanism that rectilinearly moves a sample 9 in two orthogonal directions on a sample placement surface, a mechanism that rectilinearly moves the sample 9 in a direction perpendicular to the sample placement surface, and a mechanism that rotates the sample 9 on the sample placement surface. The sample stage 10 further includes a tilting feature capable of changing an irradiation angle of an ion beam 14 with respect to the sample 9 by rotating the sample 9 about a tilting axis. Control of these mechanisms is executed by the sample stage controller 97 according to a command sent from the calculation processing device 99.

Next, an action of the field ionization ion source of this example will be described below. Herein, a description will be made on the assumption that an ionization gas is hydrogen. First, hydrogen is fully stored in the non-evaporable getter 70. Thereafter, the ion source evacuation pump 12 is used to evacuate the vacuum chamber 68. The valve 74 capable of performing vacuum blocking while being interposed between the vacuum chamber 71 accommodating the non-evaporable getter and the vacuum chamber 68 is closed.

After evacuation is completed, when a sufficiently long time has elapsed, the refrigerator 4 is operated. Accordingly, the emitter tip 21 and extraction electrode 24 are cooled down.

Thereafter, the valve 69 capable of performing vacuum blocking while being interposed between the evacuation pump 12 and vacuum chamber is closed. The non-evaporable getter is then heated in order to desorb a stored hydrogen gas. Incidentally, the hydrogen gas desorbed from the non-evaporation getter or a hydrogen storing alloy has been thought to exhibit a sufficient purity. The present inventor has found that when an impurity gas such as oxygen or nitrogen which is concurrently desorbed at that time is introduced into the ionization chamber, the impurity gas is adsorbed by the emitter tip and a hydrogen ion beam becomes unstable. A membrane 75 that selectively permeates hydrogen, for example, a palladium membrane is used to purify the gas desorbed from the non-evaporable getter or hydrogen storing alloy, and a hydrogen gas is introduced into the gas-molecule ionization chamber 15 through the gas supply piping 25. At this time, if the temperature of the non-evaporable getter is controlled, there is exerted the advantage that a desorbing quantity, that is, a hydrogen gas pressure in the ionization chamber can be appropriately adjusted.

As mentioned above, the gas-molecule ionization chamber has a high degree of vacuum. Therefore, a ratio at which an ion beam produced by the emitter tip 21 collides with a residual gas in the gas-molecule ionization chamber and gets neutralized decreases. Therefore, a large-current ion beam can be produced. The number of high-temperature hydrogen gas molecules that collide against the extraction electrode decreases. Accordingly, the cooling temperature for the emitter tip and extraction electrode can be lowered. Eventually, a large-current ion beam can be irradiated to a sample.

Thereafter, a voltage is applied between the emitter tip 21 and extraction electrode 24. A strong electric field is formed at the distal end of the emitter tip. Hydrogen supplied through the gas supply piping 25 is attracted to the emitter tip surface owing to the strong electric field. The hydrogen reaches the vicinity of the distal end of the emitter tip 21 in which the electric field is the strongest. The hydrogen is field-ionized and a hydrogen ion beam is produced. The hydrogen ion beam is introduced into the ion beam irradiation system by way of the hole 27 of the extraction electrode 24.

A hydrogen gas introduced into the ionization chamber, that is, a hydrogen gas that is not ionized after being supplied to the perimeter of the emitter tip is, in this specification, expressed as a gas that is not used at the emitter tip.

Next, an action of the ion beam irradiation system of the ion microscope of this example will be described below. The action of the ion irradiation system is controlled in response to a command sent from the calculation processing device 99. An ion beam 14 produced by the gas field ion source 1 is focused by the focusing lens 5, has the beam diameter thereof limited by the beam limiting aperture 6, and converged by the objective lens 8. The converged beam is irradiated to the sample 9 on the sample stage 10 while being swept.

Secondary particles released from a sample are detected by the secondary particle detector 11. A signal from the secondary particle detector 11 is luminance-modulated and sent to the calculation processing device 99. The calculation processing device 99 produces a scanning ion microscope image, and displays it on the image display unit. Thus, high-resolution observation of a sample surface is realized.

The mass separator of the ion beam irradiation system may be activated in order to remove a molecular ion beam formed with two or more hydrogen atoms. A proton beam alone may be selected and irradiated to a sample. This has the advantage that the diameter of an ion beam is decreased and higher-resolution observation is realized.

A magnetic material may be adopted as the vacuum chamber material of the field ionization ion source, ion beam irradiation system, and sample chamber in order to shield an external magnetic field. This has the advantage that the diameter of an ion beam is decreased and higher-resolution observation is realized.

When an apparatus constitution has the tilting mechanism, which changes the inclination of the emitter tip, excluded therefrom, the inclination of the focusing lens may be adjusted in line with the direction of an ion beam emitted from the distal end of the emitter tip. This has the advantage that a distortion of the ion beam caused by the focusing lens is diminished, the diameter of the ion beam is decreased, and higher-resolution observation is realized. In addition, there is exerted the advantage that since the tilting mechanism for the emitter tip 21 can be excluded, an ion source structure can be simplified and a low-cost apparatus can be realized.

Further, another vacuum apparatus may be used to observe an ion emission pattern from the emitter tip in order to precisely adjust the tilting direction of the emitter tip. The result of the adjustment may be introduced into the apparatus of the present embodiment. In this case, the tilting mechanism that changes the inclination of the emitter tip can be excluded or a tilting range can be narrowed. This has the advantage that an ion source structure can be simplified and a low-cost apparatus can eventually be realized.

By the way, part of a hydrogen gas introduced into the gas-molecule ionization chamber is irradiated as an ion beam to a sample, but almost all the hydrogen gas is exhausted by the vacuum pump. In the present embodiment, first, the valve 76 capable of performing vacuum blocking while being interposed between the vacuum chamber 71 accommodating the non-evaporable getter 70 and the ionization chamber 15 is closed. Thereafter, the valve 74 capable of performing vacuum blocking while being interposed between the vacuum chamber 71 accommodating the non-evaporable getter 70 and the vacuum chamber 68 of the gas field ion source is opened. The valve capable of performing vacuum blocking while being interposed between the vacuum pump and the vacuum chamber of the gas field ion source is closed. Accordingly, the hydrogen gas in the vacuum chamber is adsorbed by the non-evaporable getter. At this time, if the non-evaporable getter is cooled, there is exerted the advantage that adsorption efficiency is upgraded, and hydrogen gas collection efficiency as well as even utilization efficiency is upgraded. In addition, at this time, the vacuum chamber 71 accommodating the non-evaporable getter highly efficiently adsorbs not only hydrogen but also an impurity gas such as nitrogen or oxygen. In other words, the vacuum chamber acts as a vacuum pump for the vacuum chamber 68. This has the advantage that the impurity gas is prevented from being adsorbed by the emitter tip 21 in order to stabilize an ion beam. Since the impurity gas such as oxygen or nitrogen remains in the vacuum chamber 71 accommodating the non-evaporable getter, the impurity gas is exhausted by the vacuum pump. The cooling mechanism for the non-evaporable getter makes it possible to quickly change from heating in a gas desorption mode to a gas adsorption mode. Namely, there is exerted the advantage that a temporally efficient apparatus action is enabled.

When hydrogen is fully collected into the non-evaporable getter, the valve 74 capable of performing vacuum blocking while being interposed between the vacuum chamber, which accommodates the non-evaporable getter, and the vacuum chamber of the gas field ion source is closed, and the non-evaporable getter is heated. Accordingly, an absorbed hydrogen gas is desorbed. At this time, if the vacuum chamber accommodating the non-evaporable getter is also heated, the hydrogen gas or impurity gas is little adsorbed by the wall of the vacuum chamber. Therefore, the hydrogen gas is more efficiently collected. If the collected hydrogen gas is finally introduced into the ionization chamber, a hydrogen ion beam is emitted. Accordingly, circulatory utilization of the hydrogen gas is enabled. Namely, a quantity of the hydrogen gas to be exhausted to the air is decreased, and a majority thereof can be utilized as the hydrogen ion beam.

The diameter of the actuation vent 67 is made as small as, for example, 2 mm. Accordingly, a quantity of a hydrogen gas that passes from the ion source to the vacuum chamber of the ion irradiation system can be decreased. This has the advantage that hydrogen gas collection efficiency is upgraded. In particular, when the conductance of the actuation vent is diminished by at least two digits or more compared with the conductance of the hydrogen gas collection pump, efficient collection is enabled.

According to the aforesaid embodiment, there is exerted the advantage that a gas field ion source exhibiting high ionization gas utilization efficiency, excellent economic efficiency, and even well consistency with global environment protection is provided.

Further, according to the aforesaid embodiment, since the temperature controller for the material that adsorbs a gas which should be ionized is included, an adsorbing quantity and desorbing quantity can be controlled. This has the advantage that a gas field ion source capable of more efficiently utilizing an ionization gas is provided.

Further, according to the aforesaid embodiment, since the heating unit and cooling unit for the material that adsorbs a gas which should be ionized are included, a large quantity can be desorbed through heating, and a large quantity can be adsorbed through cooling. This has the advantage that a gas field ion source capable of more efficiently unitizing an ionization gas is provided.

Further, according to the aforesaid embodiment, after a gas which should be ionized is stored in advance in the material that adsorbs the gas which should be ionized, the gas field ion source is evacuated. This has the advantage that a gas field ion source that can introduce a large quantity of a gas into a vacuum unit and enjoys a long service life is provided.

Further, according to the aforesaid embodiment, the material that adsorbs a gas which should be ionized is the non-evaporable getter. Accordingly, the degree of vacuum of the vacuum chamber is improved. This has the advantage that a gas field ion source which diminishes adsorption of an impurity gas by the acicular ion emitter so as to stabilize an ion beam and which exhibits high ionization gas utilization efficiency is provided.

Further, according to the aforesaid embodiment, the material that selectively permeates a gas which should be ionized is interposed between the material that adsorbs the gas which should be ionized and the emitter tip. Accordingly, an impurity gas is removed from a gas desorbed from the material that adsorbs the gas which should be ionized. This has the advantage that a gas field ion source which diminishes adsorption of the impurity gas by the acicular ion emitter so as to stabilize an ion beam, and which exhibits high ionization gas utilization efficiency is provided. This is attributable to the fact that the present inventor has brought it, which has not been discussed in the past, to light that a phenomenon that an impurity gas is released at the same time when a gas is desorbed from a material that adsorbs the gas which should be ionized adversely affects stability of an ion beam.

Further, according to the aforesaid embodiment, the valve capable of performing vacuum blocking is interposed between the material that adsorbs a gas which should be ionized and the vacuum chamber. Accordingly, an impurity gas to be released at the same time when a gas is desorbed from the material that adsorbs the gas which should be ionized is prevented from being introduced into the vacuum chamber. This has the advantage that a gas field ion source which diminishes adsorption of the impurity gas by the acicular ion emitter so as to stabilize an ion beam, and which exhibits high ionization gas utilization efficiency is provided.

Further, according to the aforesaid embodiment, the valve capable of performing vacuum blocking is used for partitioning, and the vacuum pump that evacuates the vacuum chamber accommodating the material that adsorbs the gas which should be ionized is disposed inside the valve. This has the advantage that the impurity gas to be released at the same time when a gas is desorbed from the material that adsorbs the gas which should be ionized can be discharged, and the vacuum chamber can be retained in high vacuum.

Further, according to the aforesaid embodiment, a gas which should be ionized is hydrogen. Therefore, adsorption efficiency is high and storage efficiency is high. This has the advantage that a gas field ion source which exhibits high ionization gas utilization efficiency is provided. In addition, there is exerted the advantage that when a hydrogen ion beam is irradiated to a sample, compared with when helium or the like is irradiated, a sample damage is limited.

Further, according to the aforesaid embodiment, in the gas field ion source, the distal end of the emitter tip is a nano-pyramid formed with atoms. This has the advantage that since an ionization region is limited, a higher-luminance ion source is formed and higher-resolution sample observation is enabled. In addition, since an entire ion current gets smaller, there is exerted the advantage that a gas field ion source exhibiting higher ionization gas utilization efficiency is provided by utilizing an ionization gas in a circulatory manner.

Further, according to the aforesaid embodiment, the gas field ion source has the acicular emitter tip that produces ions, the extraction electrode opposed to the emitter tip, and the ionization chamber, which is formed to enclose the emitter tip, included in the vacuum chamber, and extracts an ion beam from the acicular emitter tip. Herein, the gas field ion source further includes the first vacuum pump which is joined to the vacuum chamber and in which the non-evaporable getter is incorporated, the mechanism that heats the non-evaporable getter, the valve capable of performing vacuum blocking while being interposed between the vacuum chamber and first vacuum pump, the second vacuum pump that exhausts the vacuum-blocked vacuum pump, and the piping that joins the vacuum pump and ionization chamber. Further, the gas field ion source includes the hydrogen selective permeation membrane in the middle of the piping. This has the advantage that a gas field ion source exhibiting high ionization gas utilization efficiency, excellent economic efficiency, and even well consistency with global environment protection is provided.

Further, according to the aforesaid embodiment, the charged particle microscope includes the gas field ion source, the focusing lens that focuses an ion beam emitted from the ion source, the deflector that deflects the ion beam having passed through the focusing lens, and the secondary particle detector that irradiates the ion beam to a sample and detects secondary particles released from the sample. This has the advantage that a charged particle microscope exhibiting high ionization gas utilization efficiency, excellent economic efficiency, and even well consistency with global environment protection is provided.

Further, according to the aforesaid embodiment, a charged particle microscopy is characterized in that, in the gas field ion source, a gas is supplied to the perimeter of the emitter tip, a gas that is not ionized by the gas field ion source is adsorbed by the material that adsorbs a gas which should be ionized, the adsorbed gas is re-emitted and supplied to the perimeter of the emitter tip, and an ion beam is extracted from the gas field ion source and used to observe or analyze a sample. This has the advantage that a charged particle microscopy offering high ionization gas utilization efficiency, excellent economic efficiency, and even well consistency with global environment protection is provided.

Incidentally, the present embodiment has been described in relation to a hydrogen gas. The present invention can be applied to any other gas as long as a material that efficiently adsorbs any of gases of oxygen, nitrogen, helium, and argon is employed.

### Embodiment 2

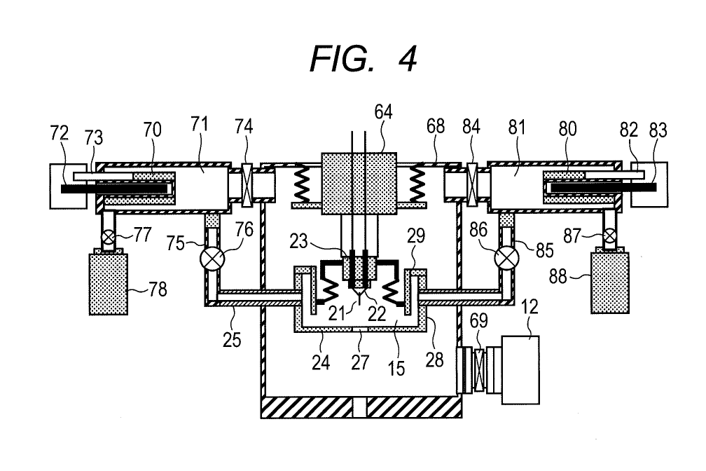

Next, referring to FIG. 4, a description will be made of an embodiment in which at least two pairs of valves capable of performing vacuum blocking are each interposed between a vacuum chamber, which accommodates a material that adsorbs a gas which should be ionized, and a vacuum chamber in the aforesaid gas field ion source.

An iterative description of contents that overlap the contents of the embodiment 1 will be omitted.

In the present embodiment, as illustrated, on the left side of FIG. 4, a valve 74 capable of performing vacuum blocking is interposed between a vacuum chamber 71, which accommodates a material that adsorbs a gas which should be ionized, and a vacuum chamber. A way of using the material on one side that adsorbs the gas which should be ionized is identical to the aforesaid way of using. Specifically, a first non-evaporable getter 70 is heated in order to desorb a stored hydrogen gas, a membrane that selectively permeates the hydrogen gas is used to purify the hydrogen gas, and the hydrogen gas is introduced into a gas-molecule ionization chamber 15 through a gas supply piping 25. Thereafter, a voltage is applied between an emitter tip 21 and an extraction electrode 24 in order to produce a hydrogen ion beam.

Thereafter, the valve 74 capable of performing vacuum blocking while being interposed between the vacuum chamber, which accommodates the first non-evaporable getter, and the vacuum chamber of a gas field ion source, and a valve 84 capable of performing vacuum blocking while being interposed between a vacuum chamber, which accommodates a second non-evaporable getter, and the vacuum chamber of the gas field ion source are alternately and repeatedly opened and closed to act. In other words, when the first non-evaporable getter 70 acts as a vacuum pump, the first valve 74 capable of performing vacuum blocking while being interposed between the vacuum chamber, which accommodates the first non-evaporable getter, and the vacuum chamber of the gas field ion source is opened. The second non-evaporable getter 80 is placed in a hydrogen gas desorption mode, and the second valve 84 capable of performing vacuum blocking is closed. In contrast, when the first non-evaporable getter acts in the hydrogen gas desorption mode, the first valve 74 capable of performing vacuum blocking is closed. When the second non-evaporable getter acts as a vacuum pump, the second valve 84 capable of performing vacuum blocking is opened.

According to the aforesaid embodiment, in the gas field ion source, at least two or more pairs of valves capable of performing vacuum blocking are each interposed between the material that adsorbs a gas which should be ionized and the vacuum chamber. When a gas is desorbed from the first material that adsorbs the gas which should be ionized, the valve capable of performing vacuum blocking while being interposed between the material and vacuum chamber is closed and the other valve capable of performing vacuum blocking is opened, so that the degree of vacuum in the vacuum chamber can be held intact. This has the advantage that a gas field ion source which diminishes adsorption of an impurity gas by the acicular ion emitter so as to stabilize an ion beam, and which exhibits high ionization gas utilization efficiency is provided.

According to the foregoing embodiment, there is exerted the advantage that a gas field ion source exhibiting high ionization gas utilization efficiency, excellent economic efficiency, and even well consistency with global environment protection is provided.

### Embodiment 3

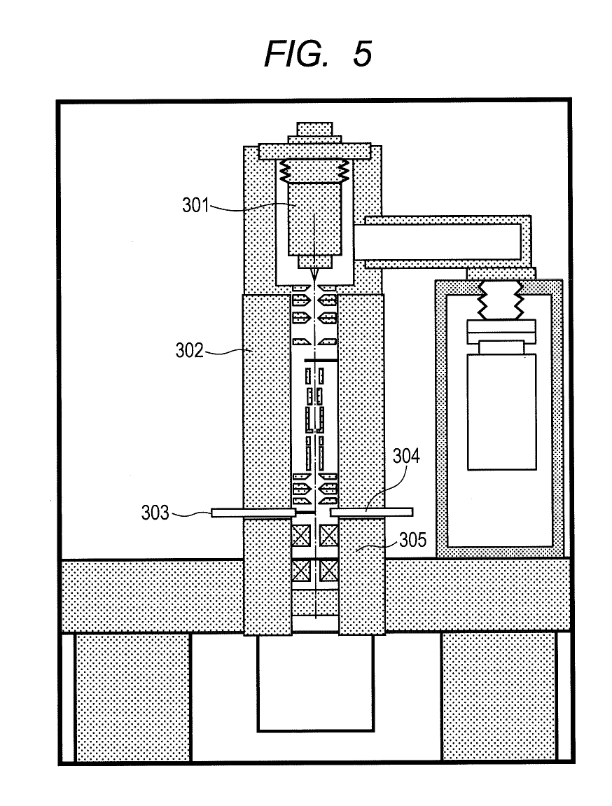

Next, referring to FIG. 5, a description will be made of a charged particle microscope that uses a hybrid particle source, which includes an emitter tip whose distal end is a nano-pyramid formed with atoms and has an ion beam or electrons extracted from the acicular emitter tip, to enable complex sample analysis based on observation of a sample surface, sample processing, and observation of a sample interior.

An iterative description of contents overlapping the contents of the embodiments 1 and 2 will be omitted.

A charged particle microscope of the present embodiment includes a hybrid particle source 301 that has an emitter tip whose distal end is a nano-pyramid formed with atoms and that extracts an ion beam or electrons from the acicular emitter tip, a hybrid irradiation system 302 that irradiates an electron beam or ion beam to a sample, a sample stage 303, a secondary particle detector 304 that detects secondary particles released from the sample, and an optical system 305 that images charged particles transmitted by the sample. Either of a positive high-voltage source or negative high-voltage source can be selected and connected to the emitter tip. Namely, when a positive high voltage is applied, a positive ion beam can be extracted. When a negative high voltage is applied, an electron beam can be extracted from the emitter tip. At least two or more kinds of gases can be introduced into the hybrid particle source. Specifically, at least two kinds of gas species including one of hydrogen and helium and one of neon, argon, krypton, xenon, nitrogen, and oxygen can be introduced.

In the present charged particle microscope, an ion beam of one of neon, argon, krypton, xenon, nitrogen, and oxygen can be extracted from the emitter tip, and irradiated to a sample ion order to process the sample. In addition, an ion beam of one of hydrogen and helium can be extracted from the acicular emitter tip in order to observe a sample surface. In addition, electrons can be extracted from the acicular emitter tip, and irradiated to the sample. Electrons transmitted by the sample are imaged, whereby sample interior information can be obtained. Accordingly, complex analysis of the sample can be achieved without the necessity of exposing the sample to the air.

In the foregoing embodiment, a charged particle microscope includes a hybrid particle source that has an emitter tip whose distal end is a nano-pyramid formed with atoms and that extracts an ion beam or electrons from the acicular emitter tip, a charged particle irradiation optical system that introduces charged particles emitted from the hybrid particle source to a sample, a secondary particle detector that detects secondary particles released from the sample, a charged particle imaging optical system that images charged particles transmitted by the sample, and a gas supply pipe through which a gas is supplied to the vicinity of the emitter tip. As the gas, at least two kinds of gas species including one of hydrogen and helium and one of neon, argon, krypton, xenon, nitrogen, and oxygen can be selected. Either of a positive high voltage power supply and negative high voltage power supply can be selected and connected to the acicular emitter tip. This has the advantage that a charged particle microscope capable of observing a sample top surface using a beam of one of hydrogen and helium, processing a sample using an ion beam of one of neon, argon, krypton, xenon, nitrogen, and oxygen, and observing a sample interior by irradiating an electron beam to the sample and detecting electrons transmitted by the sample is provided. In particular, when a nano-pyramid emitter tip is employed, an extremely small-diameter ion beam or extremely small-diameter electron beam can be obtained. This has the advantage that a charged particle microscope capable of analyzing sample information on the order of a sub-nanometer is provided.

Further, in the foregoing embodiment, a hybrid charged particle microscopy is such that: the distal end of an emitter tip is a nano-pyramid formed with atoms; an ion beam of one of neon, argon, krypton, xenon, nitrogen, and oxygen is extracted from the acicular emitter tip, and irradiated to a sample in order to process the sample; an ion beam of one of hydrogen and helium is extracted from the acicular emitter tip in order to observe a sample surface; and electrons are extracted from the acicular emitter tip, and irradiated to the sample so that electrons transmitted by the sample are imaged in order to obtain sample interior information. This has the advantage that complex sample analysis based on observation of a sample surface, processing of a sample, and observation of a sample interior is enabled. In particular, when a nano-pyramid emitter tip is employed, there is exerted the advantage that a charged particle microscopy permitting sample information analysis based on an extremely small-diameter ion beam and extremely small-diameter electron beam is provided.

### DESCRIPTION OF REFERENCE NUMERALS

1: gas field ion source, 2: ion beam irradiation system column, 3: sample chamber, 4: cooling mechanism, 5: focusing lens, 6: movable aperture, 7: deflector, 8: objective lens, 9: sample, 10: sample stage, 11: secondary particle detector, 12: ion source evacuation pump, 13: sample chamber evacuation pump, 14: ion beam, 14A: optical axis, 15: gas-molecule ionization chamber, 16: compressor, 17: apparatus gantry, 18: base plate, 19: vibration isolation mechanism, 20: floor, 21: emitter tip, 22: filament, 23: filament mount, 24: extraction electrode, 25: gas supply piping, 27: opening, 28: sidewall, 29: top panel, 35: first deflector, 36: second aperture, 64: emitter base mount, 67: actuation vent, 68: vacuum chamber, 69: valve capable of performing vacuum blocking, 70: non-evaporable getter, 71: vacuum chamber, 72: heating mechanism, 73: cooling mechanism, 74: valve capable of performing vacuum blocking, 75: material that selectively permeates a gas which should be ionized, 76: valve capable of performing vacuum blocking, 77: valve capable of performing vacuum blocking, 78: vacuum pump, 91: field ionization ion source controller, 92: refrigerator controller, 93: lens controller, 94: first aperture controller, 95: ion beam scanning controller, 96: secondary particle detector controller, 97: sample stage controller, 98: evacuation pump controller, 99: calculation processing device, 195: first deflector controller, 196: temperature controller.

1-17. (canceled)

18. A charged particle microscope comprising:
a vacuum chamber;
a first pump that exhausts the vacuum chamber;
an emitter tip disposed in the vacuum chamber;
an extraction electrode opposed to the emitter tip; and
a gas supply means that supplies a gas to the emitter tip, wherein
the gas supply means includes a second pump that circulates a gas which is not used at the emitter tip; and
the second pump includes a gas adsorption material that adsorbs the gas.

19. The charged particle microscope as set forth in claim 18, wherein the charged particle microscope further comprises a temperature control means that controls the temperature of the gas adsorption material.

20. The charged particle microscope as set forth in claim 18, wherein the charged particle microscope further comprises a means that heats the gas adsorption material and a temperature control means that cools the gas adsorption material.

21. The charged particle microscope as set forth in claim 18, wherein a gas is adsorbed by the gas adsorption material in advance and the first pump is driven.

22. The charged particle microscope as set forth in claim 18, wherein the gas adsorption material is a non-evaporable getter.

23. The charged particle microscope as set forth in claim 18, wherein the gas supply means includes:
a first channel that is a gas channel extending from the vacuum chamber to a first vacuum chamber in which the gas adsorption material is accommodated;
a second channel that is a gas channel extending from the first vacuum chamber to the vacuum chamber; and
a gas selective-permeation means that selectively permeates a gas into the second channel.

24. The charged particle microscope as set forth in claim 23, wherein a valve is disposed in the first channel.

25. The charged particle microscope as set forth in claim 23, wherein a valve is formed in the first channel and second channel.

26. The charged particle microscope as set forth in claim 23, wherein the first vacuum chamber is provided with a third pump.

27. The charged particle microscope as set forth in claim 23, wherein the gas selective-permeation means is a hydrogen selective-permeation membrane.

28. The charged particle microscope as set forth in claim 18, wherein the gas is hydrogen.

29. The charged particle microscope as set forth in claim 18, wherein the gas contains at least one of hydrogen, helium, neon, argon, krypton, and xenon.

30. The charged particle microscope as set forth in claim 18, wherein the emitter tip is realized with a nano-pyramid.

31. An ion microscope comprising:
a vacuum chamber;
a first pump that exhausts the vacuum chamber;
an emitter tip disposed in the vacuum chamber;
an extraction electrode opposed to the emitter tip;
a gas supply means that supplies a gas to the emitter tip;
a focusing lens that focuses an ion beam emitted from the emitter tip;
a deflector that deflects the ion beam which has passed through the focusing lens; and
a secondary particle detector that irradiates the ion beam to a sample and detects secondary particles released from the sample, wherein
the gas supply means includes a second pump that circulates a gas which is not used at the emitter tip; and
the second pump includes a gas adsorption material that adsorbs the gas.

32. A charged particle microscope comprising:
a vacuum chamber;
a first pump that exhausts the vacuum chamber;
an emitter tip disposed in the vacuum chamber;
an extraction electrode opposed to the emitter tip;
a gas supply means that supplies a gas to the emitter tip;
a focusing lens that focuses a charged-particle beam emitted from the emitter tip;
a deflector that deflects the charged-particle beam which has passed through the focusing lens; and
a secondary particle detector that irradiates the charged-particle beam to a sample and detects secondary particles released from the sample, wherein
a positive voltage or negative voltage can be selectively applied to the emitter tip;
the gas supply means includes a second pump that circulates a gas which is not used at the emitter tip; and
the second pump includes a gas adsorption material that adsorbs the gas.

33. The charged particle microscope as set forth in claim 32, wherein the gas includes one of hydrogen and helium and at least one of neon, argon, krypton, xenon, nitrogen, and oxygen.

34. The charged particle microscope as set forth in claim 32, wherein the charged particle microscope further comprises a selection means capable of selecting
a mode in which an ion beam deriving from at least one of gases of neon, argon, krypton, xenon, nitrogen, and oxygen is utilized through the emitter tip in order to process a sample,
a mode in which an ion beam deriving from one of gases of hydrogen and helium is utilized through the emitter tip in order to observe a sample, or
a mode in which an electron beam stemming from the emitter tip is utilized in order to observe a sample.
